(19) United States
(12) Patent Application Publication
(10) Pub. No.: US 2010/0123197 A1
(43) Pub. Date: May 20, 2010

(54) SEMICONDUCTOR DEVICE AND METHOD OF MANUFACTURING THE SAME

(75) Inventor: Zhengwu Jin, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/563,324

(22) Filed: Sep. 21, 2009

(30) Foreign Application Priority Data
Nov. 17, 2008 (JP) 2008-293802

(51) Int. Cl. H01L 27/092; H01L 21/336; H01L 29/78

(52) U.S. Cl. 257/369; 438/294; 257/288; 257/E21.409; 257/E29.255; 257/E27.062

(57) ABSTRACT

A semiconductor device includes an insulated-gate field-effect transistor including a gate electrode provided on a semiconductor substrate, and a source and a drain provided spaced apart in the semiconductor substrate in a manner to sandwich the gate electrode, the insulated-gate field-effect transistor having electrons or holes as carriers, and an element isolation insulation film having a negative expansion coefficient, which is disposed in the semiconductor substrate in an element isolation region along a channel width direction and a channel length direction in a manner to surround the insulated-gate field-effect transistor, the element isolation insulation film applying a tensile stress by operation heat to the insulated-gate field-effect transistor in two axial directions that are the channel width direction and the channel length direction.

### CROSS-REFERENCE TO RELATED APPLICATIONS

This application is based upon and claims the benefit of priority from prior Japanese Patent Application No. 2008-293802, filed Nov. 17, 2008, the entire contents of which are incorporated herein by reference.

### BACKGROUND OF THE INVENTION

1. Field of the Invention

The present invention relates to a semiconductor device and a method of manufacturing the same.

2. Description of the Related Art

Conventionally, as one of active elements constituting a large-scale integration (LSI) circuit, there is known an insulated-gate field-effect transistor (hereinafter referred to as “transistor”) which is typified by a MOS (metal oxide semiconductor) transistor or a MIS (metal insulator semiconductor) transistor. With further microfabrication of such transistors, the number of transistors in an LSI becomes enormous. Thus, in proportion to the number of transistors, the amount of heat produced by the LSI becomes greater. As a result, the lattice vibration of a crystal lattice of silicon, etc., which constitutes a transistor, becomes large, and the resultant thermal disturbance becomes a factor which decreases the mobility of electrons or holes (carriers).

Under the circumstance, there has been proposed a semiconductor device wherein a desired stress is applied to a channel region of a transistor, for example, by means of an insulating material, thereby improving the mobility of electrons or holes which are carriers (see, for instance, Jpn. Pat. Appln. KOKAI Publication No. 2004-63591).

### BRIEF SUMMARY OF THE INVENTION

According to an aspect of the present invention, there is provided a semiconductor device comprising: an insulated-gate field-effect transistor including a gate electrode provided on a semiconductor substrate, and a source and a drain provided spaced apart in the semiconductor substrate in a manner to sandwich the gate electrode, the insulated-gate field-effect transistor having electrons or holes as carriers; and an element isolation insulation film having a negative expansion coefficient, which is disposed in the semiconductor substrate in an element isolation region along a channel width direction and a channel length direction in a manner to surround the insulated-gate field-effect transistor, the element isolation insulation film applying a tensile stress by operation heat to the insulated-gate field-effect transistor in two axial directions that are the channel width direction and the channel length direction.

According to another aspect of the present invention, there is provided a semiconductor device comprising: a first insulated-gate field-effect transistor including a gate electrode provided on a semiconductor substrate, and a source and a drain provided spaced apart in the semiconductor substrate in a manner to sandwich the gate electrode, the first insulated-gate field-effect transistor having electrons as carriers; a second insulated-gate field-effect transistor including a gate electrode provided on the semiconductor substrate, and a source and a drain provided spaced apart in the semiconductor substrate in a manner to sandwich the gate electrode, the second insulated-gate field-effect transistor having holes as carriers; a first element isolation insulation film having a negative expansion coefficient, which is buried in a trench in an element isolation region of the semiconductor substrate, the first element isolation insulation film applying a tensile stress by operation heat to the first insulated-gate field-effect transistor; and a second element isolation insulation film having a positive expansion coefficient, which is buried in a trench in an element isolation region of the semiconductor substrate, the second element isolation insulation film applying a compressive stress by operation heat to the second insulated-gate field-effect transistor.

According to still another aspect of the present invention, there is provided a method of manufacturing a semiconductor device, comprising: forming a trench for element isolation in a semiconductor substrate in an element isolation region along two axial directions that are a channel width direction and a channel length direction; burying a silicon oxide film in the trench; doping a crystal seed in the silicon oxide film; performing a first heat treatment process on the silicon oxide film, thereby making the silicon oxide film in a glass state; performing a second heat treatment process on the silicon oxide film in the glass state, thereby precipitating a crystal nucleus in an amorphous matrix layer in the silicon oxide film; performing a third heat treatment process on the amorphous matrix layer including the crystal nucleus, thereby growing the crystal nucleus into a crystal line and forming an element isolation insulation film including a glass ceramics layer; forming a gate insulation film on the semiconductor substrate in an element region; forming a gate electrode on the gate insulation film; and forming a source and a drain spaced apart in the semiconductor substrate in a manner to sandwich the gate electrode.

### BRIEF DESCRIPTION OF THE SEVERAL VIEWS OF THE DRAWING

FIG. 1 is a plan view showing a semiconductor device according to a first embodiment of the present invention;

FIG. 2 is a cross-sectional view taken along line II-II in FIG. 1;

FIG. 3 is a plan view for explaining the driving operation of the semiconductor device according to the first embodiment;

FIG. 4 is a cross-sectional view for explaining the driving operation of the semiconductor device according to the first embodiment;

FIG. 5 is a timing chart showing the relationship between the time and temperature according to the first embodiment;

FIG. 6 is a cross-sectional view illustrating a fabrication step of the semiconductor device according to the first embodiment;

FIG. 7 is a cross-sectional view illustrating a fabrication step of the semiconductor device according to the first embodiment;

FIG. 8 is a cross-sectional view illustrating a fabrication step of the semiconductor device according to the first embodiment;

FIG. 9 is a cross-sectional view illustrating a fabrication step of the semiconductor device according to the first embodiment;

FIG. 10 is a cross-sectional view illustrating a fabrication step of the semiconductor device according to the first embodiment;

FIG. 11 is a graph showing the relationship between the temperature and the crystal nucleus formation rate/crystal nucleus growth rate according to the first embodiment;

FIG. 12 is a plan view for explaining the driving operation of a semiconductor device according to a modification;

FIG. 13 is a cross-sectional view for explaining the driving operation of the semiconductor device according to the modification;

FIG. 14 is a view for explaining a fabrication step of the semiconductor device according to the modification;

FIG. 15 is a plan view showing a semiconductor device according to a second embodiment of the present invention;

FIG. 16 is a cross-sectional view taken along line XVI-XVI in FIG. 15;

FIG. 17 is a plan view for explaining the driving operation of the semiconductor device according to the second embodiment;

FIG. 18 is a cross-sectional view for explaining the driving operation of the semiconductor device according to the second embodiment;

FIG. 19 is a plan view showing a semiconductor device according to a third embodiment of the present invention;

FIG. 20 is a cross-sectional view taken along line XX-XX in FIG. 19;

FIG. 21 is a plan view for explaining the driving operation of the semiconductor device according to the third embodiment;

FIG. 22 is a cross-sectional view for explaining the driving operation of the semiconductor device according to the third embodiment;

FIG. 23 is a plan view showing a semiconductor device according to a fourth embodiment of the present invention;

FIG. 24 is a cross-sectional view taken along line XXIV-XXIV in FIG. 23;

FIG. 25 is a plan view for explaining the driving operation of the semiconductor device according to the fourth embodiment;

FIG. 26 is a cross-sectional view for explaining the driving operation of the semiconductor device according to the fourth third embodiment;

FIG. 27 is a plan view showing a semiconductor device according to a fifth embodiment of the present invention;

FIG. 28 is a cross-sectional view taken along line XXVIII-XXVIII in FIG. 27;

FIG. 29 is a plan view for explaining the driving operation of the semiconductor device according to the fifth embodiment;

FIG. 30 is a cross-sectional view for explaining the driving operation of the semiconductor device according to the fifth embodiment;

FIG. 31 is a plan view showing a semiconductor device according to a sixth embodiment of the present invention; and

FIG. 32 is a plan view for explaining the driving operation of the semiconductor device according to the sixth embodiment.

### DETAILED DESCRIPTION OF THE INVENTION

In the above-described semiconductor device or the like, in which the mobility of electrons or holes that are carriers is enhanced by applying a desired stress to the channel region of the transistor, however, the stress that can be applied by the insulating material is constant, relative to the temperature rise of the semiconductor substrate, etc. Consequently, if the temperature of the LSI rises from room temperature to a high temperature (e.g. about 200° C.), there is a tendency that the effect by the stress becomes deficient due to an intensified thermal disturbance of silicon, etc., and the mobility of electrons or holes decreases.

Embodiments of the invention, which are to be described below, propose semiconductor devices and manufacturing methods thereof, which can make the mobility of carriers higher as the temperature becomes higher. The embodiments of the invention will now be described with reference to the accompanying drawings. In the description below, common parts are denoted by like reference numerals throughout the drawings.

### FIRST EMBODIMENT

### An Example of a Unit NMOS Transistor

### <1. Structure Example>

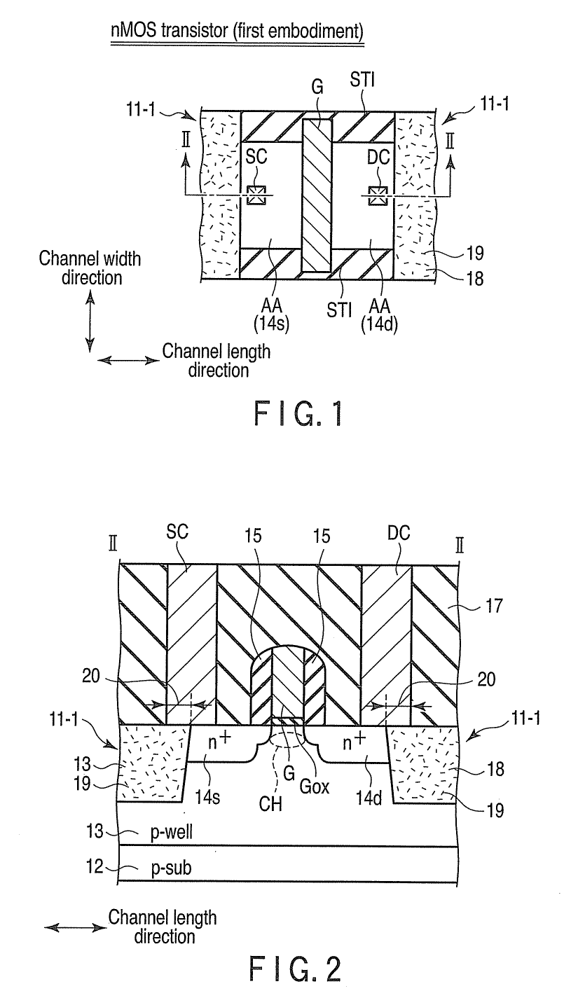

To begin with, referring to FIG. 1 and FIG. 2, a semiconductor device according to a first embodiment of the present invention is described.

As shown in FIG. 1 and FIG. 2, a semiconductor device (nMOS transistor) according to the embodiment is disposed in an element region of a semiconductor substrate (p-sub). In an element isolation region of the semiconductor substrate 12, a first element isolation insulation film 11-1 and an element isolation insulation film STI (Shallow Trench Isolation) are disposed in a manner to surround the nMOS transistor.

The nMOS transistor includes a gate insulation film Gox provided on a p-well which is formed in the semiconductor substrate 12, a gate electrode G provided on the gate insulation film Gox, a source 14s and a drain 14d provided spaced apart in the semiconductor substrate 12 in a manner to sandwich the gate electrode G, spacers 15 provided on side walls of the gate electrode G, and contact wiring lines SC and DC. This nMOS transistor is an insulated-gate field-effect transistor having electrons, which are doped n-type impurities, as carriers.

The gate insulation film Gox is formed of, for example, a silicon oxide film (SiO₂) by a thermal oxidation method.

The gate electrode G is formed of, for example, polysilicon (poly-Si).

The source 14s and drain 14d (n⁺ layer) are formed such that n-type impurities, such as phosphorus (P), arsenic (As) or antimony (Sb), are doped, for example, by ion implantation and are thermally diffused. The doped n-type impurities release free electrons serving as carriers.

The spacers 15 are formed of, e.g. a silicon nitride (SiN) film.

The contact wiring lines SC and DC are provided in an interlayer insulation film 17 on the source 14s and drain 14d. Parts of the contact wiring lines SC and DC are provided on fringe portions 20 of the first element isolation insulation films 11-1.

The first element isolation insulation film 11-1 is buried in a trench in the element isolation region of the semiconductor substrate 12, has a negative expansion coefficient, and applies a tensile stress to the nMOS transistor by operation heat.

The negative expansion coefficient (negative expansion factor) [ΔV/V/ΔT] (V: volume, T: temperature, ΔT: volume variation) refers to a ratio at which the volume decreases in accordance with an increase in temperature. The expansion coefficient of the first element isolation insulation film 11-1 is, for example, about −8×10⁻⁶/K.

The first element isolation insulation film 11-1 in this embodiment is a glass ceramics layer including an amorphous matrix layer 18, and crystal lines 19 which are dispersed in the amorphous matrix layer 18. The composition of the glass ceramics layer may be any combination of four compositions, i.e. Li₂O—Al₂O₃—SiO₂—TiO2, which can make the glass ceramics layer in a glass state.

The crystal lines 19 have a negative expansion coefficient, and the amorphous matrix layer 18 has a positive expansion coefficient. Thus, it is desirable that the ratio of the crystal lines 19 in the entire first element isolation insulation film 11-1 be greater than the ratio of the amorphous matrix layer 18 in the entire first element isolation insulation film 11-1.

As will be described later, when the device, such as the nMOS transistor, operates, the first element isolation insulation film 11-1 contracts in accordance with the rise in temperature by the operation heat of the device. As a result, a tensile stress is applied to the channel region CH along the channel length direction, the mobility of electrons is enhanced, and the characteristics of the nMOS transistor can advantageously be improved. For example, in the present embodiment, the tensile stress is about 80 to 100 GPa.

The element isolation insulation film STI is formed of, e.g. a silicon oxide (SiO₂) film which is buried in a trench for element isolation in the semiconductor substrate 12.

### <2. Application of Stress at Time of Driving Operation>

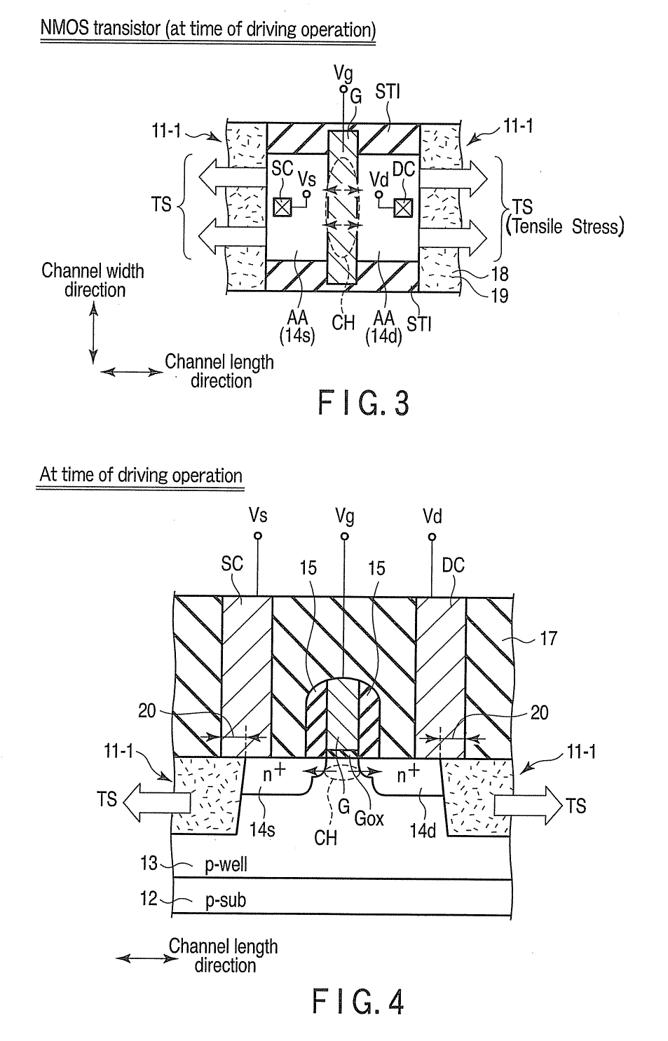

Next, referring to FIG. 3 and FIG. 4, a description is given of the application of stress at the time of the driving operation of the semiconductor device according to the first embodiment of the invention.

As shown in FIG. 3 and FIG. 4, in the above-described structure, when the nMOS transistor is driven, a source voltage Vs, a drain voltage Vd and a predetermined gate voltage Vg are applied. Then, electrons, which are carriers, move in the channel CH which is formed in the semiconductor substrate 12 below the gate electrode G. Thereby, the electrons flow between the source 14s and drain 14d, and a switching operation is performed. At this time, operation heat is produced by the application voltage, such as the drain voltage Vd, and the switching current.

If the operation heat is conducted to the first element isolation insulation layer 11-1, the first element isolation insulation layer 11-1 contracts in accordance with its own negative expansion coefficient. Accordingly, a tensile stress TS occurs in the first element isolation insulation layer 11-1 along the channel length direction. As a result, the tensile stress is applied to the channel region CH along the channel length direction. The tensile stress TS is, e.g. about 80 to 100 GPa.

Hence, even in the case where the temperature of the semiconductor substrate 12, etc. rises to high temperatures, the mobility of electrons, which are carriers of the nMOS transistor, can be increased.

In the case of this embodiment, parts of the contact wiring lines SC and DC are provided on the fringe portions 20 of the first element isolation insulation films 11-1. Thus, also because the operation heat occurring in the contact wiring lines SC and DC is directly conducted to the first element isolation insulation films 11-1, the mobility of electrons can advantageously be improved.

Needless to say, the same operation can be obtained, not only by the above-described operation heat occurring due to the driving operation of the nMOS transistor, but also by the operation heat, in a broader sense, occurring when the LSI including this nMOS transistor is operated.

### <3. Manufacturing Method>

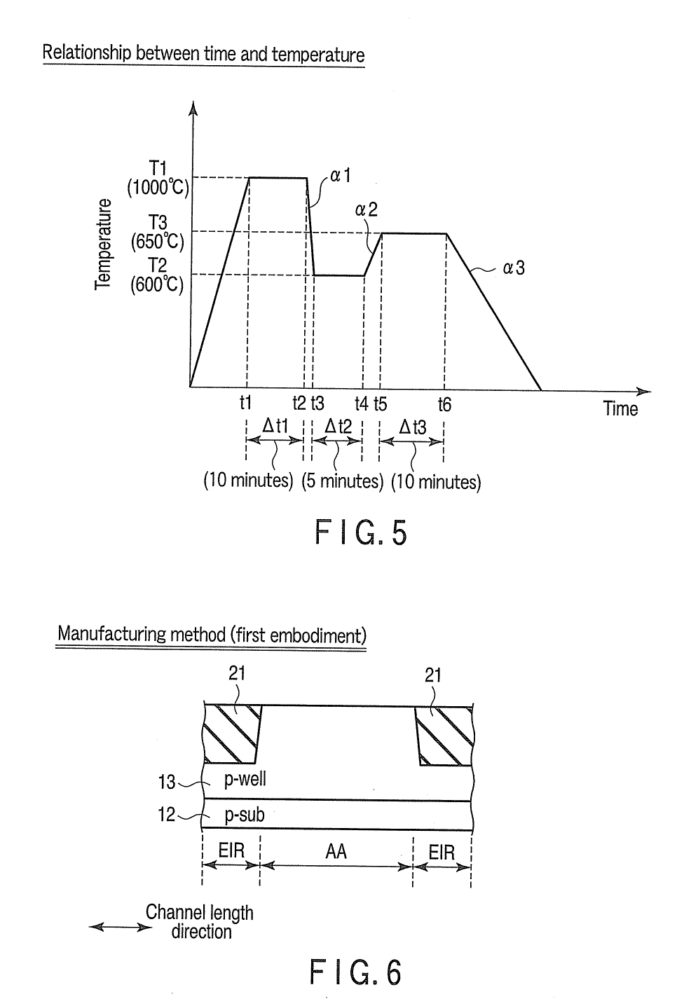

Next, referring to FIG. 5 to FIG. 11, a description is given of a method of manufacturing the semiconductor device according to the first embodiment of the invention. The description below is given on the basis of the timing chart of FIG. 5.

To begin with, p-type impurities, such as phosphorus (P), are doped in the semiconductor substrate 12, and a p-well 13 is formed (not shown).

Then, as shown in FIG. 6, a trench for element isolation is formed in an element isolation region EIR of the semiconductor substrate 12, for example, by using RIE (Reactive Ion Etching). A silicon oxide (SiO₂) film, for instance, is buried in the trench by, e.g. CVD (Chemical Vapor Deposition), and a silicon oxide film 21 is formed.

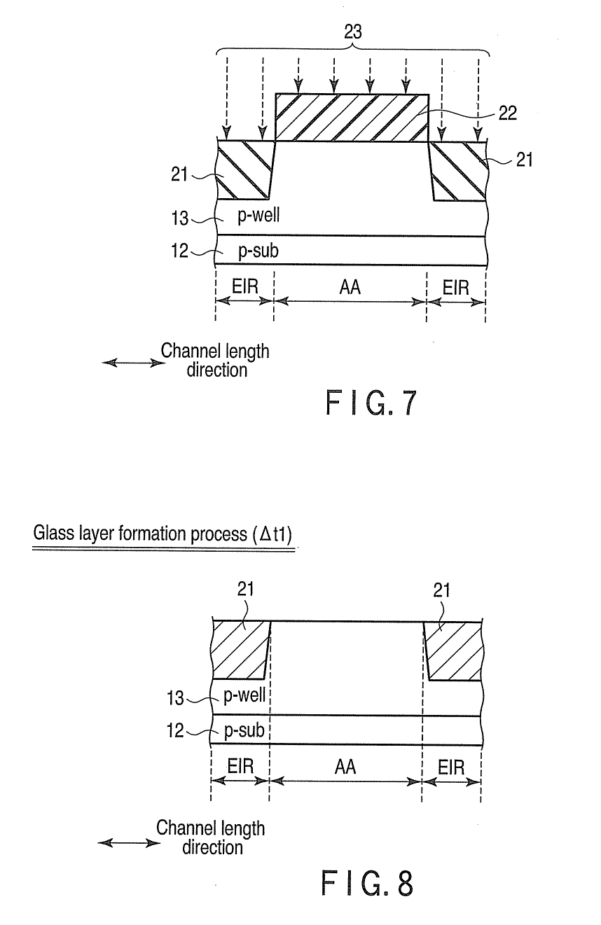

Subsequently, as shown in FIG. 7, a photoresist, for instance, is coated on the semiconductor substrate 12, and the photoresist is exposed and developed. Thereby, the photoresist is left on an element region AA (Active Area), and a mask layer 22 is formed.

Using the mask layer 22 as a mask, crystal seeds 23 of ions of, e.g. lithium (Li), aluminum (Al) or titanium (Ti), are doped in the silicon oxide film 21 by, e.g. ion implantation.

Then, as shown in FIG. 8, the mask layer 22 is removed, and heat treatment is performed, for example, in an oxidizing atmosphere during a time Δt1 (e.g. about 10 minutes) between time points t1 and t2 at a temperature T1 (e.g. about 1000° C.). Thereby, the silicon oxide film 21 is changed into a glass state (amorphous state).

Subsequently, at time point t2, the resultant structure is cooled to a temperature T2 (e.g. about 600° C.) at a temperature-lowering rate α1. Preferably, the rate α1 should be as high as possible.

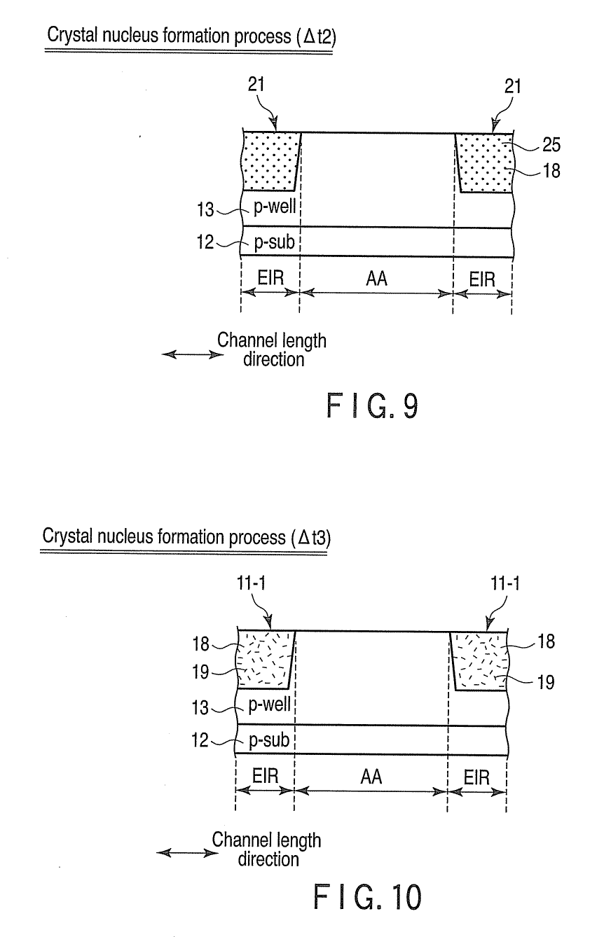

Then, as shown in FIG. 9, the silicon oxide film 21, which is in the glass state, is annealed during a time Δt2 (e.g. about 5 minutes) between time points t3 and t4 at a temperature T2 (e.g. about 600° C.). Crystal nuclei 25 are precipitated at high density in the amorphous matrix layer 18 in the silicon oxide film 21. The size of each crystal nucleus 25 is, e.g. about several nm (nanometers).

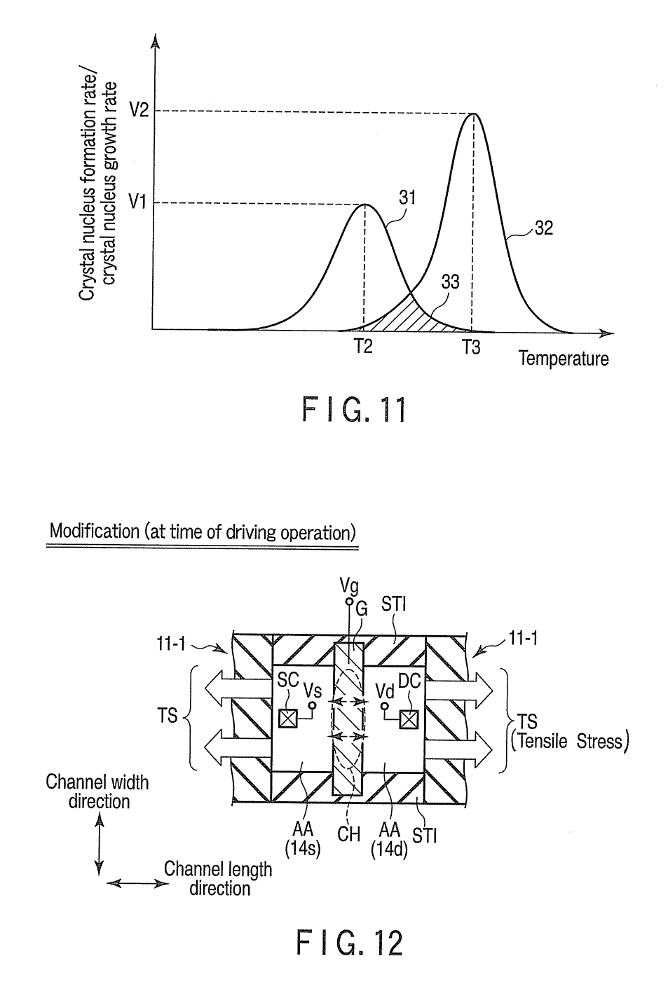

In the above process (time points t3 to t4), the temperature, at which the heat treatment is conducted, should preferably be the temperature T2 (about 600° C. in this embodiment) at which the crystal nuclei 25 are precipitated at the highest rate. Specifically, as indicated by a solid line 31 in FIG. 11, since the rate of precipitation of crystal nuclei 25 is the highest rate V1 at the temperature T2, the crystal nuclei 25 can be formed at high density in a short time.

At time point t4, the temperature of the amorphous matrix layer 18 including the crystal nuclei 25 is raised to a temperature T3 (e.g. about 650° C.) at a temperature-raising rate α2. Preferably, the temperature-raising rate α2 should be as high as possible in order to prevent non-uniform growth of the crystal nuclei 25.

Subsequently, as shown in FIG. 10, the amorphous matrix layer 18 including the crystal nuclei 25 is annealed during a time Δt3 (e.g. about 10 minutes) between time points t5 and t6 at a temperature T3 (e.g. about 650° C.). Thereby, the crystal nuclei 25 are grown, and the crystal lines 19 are formed. At the same time, by growing the crystal nuclei 25 and forming the crystal lines 19, the ions (crystal seeds) 23, which are doped in the amorphous matrix layer 18 by the ion implantation, are sufficiently precipitated. As a result, the first element isolation insulation film 11-1 can be formed of the glass ceramics layer including the amorphous matrix layer 18 and crystal lines 19. The size of the crystal line 19 is, e.g. several nm to several-ten nm.

In the above process (time points t5 to t6), it is preferable that the temperature for annealing be the temperature T3 at which the crystal nuclei 25 grow at the highest rate. Specifically, as indicated by a solid line 32 in FIG. 11, the rate of growth of crystal nuclei 25 is the highest rate V2 at the temperature T3, and the crystal nuclei 25 grow in a short time.

It is not desirable to perform annealing in a region 33 surrounded by solid lines 31 and 32 in FIG. 11. The reason for this is that in the region 33 the density of crystal nuclei 25 is becomes low, and sufficient growth cannot be achieved.

At time point t6, the first element isolation insulation film 11-1 is cooled down to room temperature or thereabout at a temperature-lowering rate a3. It is desirable that the rate a3 be as low as possible, in order to relax the internal stress which has occurred due to the crystal growth.

By the above-described process, the first element isolation insulation film 11-1, which is formed of the glass ceramics (pyroceramics) layer, can be fabricated. The composition of the glass ceramics shown in the present embodiment is merely an example, and it is possible to adopt any composition, such as a combination of Li₂O—Al₂O₃—SiO₂—TiO2, which can realize an amorphous state.

Although not shown, a gate insulation film Gox is formed in the element region AA on the semiconductor substrate 12, for example, by thermal oxidation. A gate electrode G is formed on the gate insulation film Gox. Spacers 15 are formed on side walls of the gate electrode G. Then, using the gate electrode G and spacers 15 as a mask, n-type impurities are doped in the semiconductor substrate 12, and a source 14c and a drain 14d are formed. Subsequently, an interlayer insulation film 17 is formed so as to cover the gate electrode G.

Thereafter, contact holes are formed in the interlayer insulation film 17 on the source 14s and drain 14d, and a polysilicon layer, for instance, is buried in the contact holes. Thereby, contact wiring lines SC and DC are formed. When the contact holes are formed, it is preferable to form the contact holes such that parts of the contact holes come in contact with the fringe portions 20 of the first element isolation insulation film 11-1.

By the above-described process, the semiconductor device according to the first embodiment is formed.

### <4. Advantageous Effects>

With the semiconductor device and the manufacturing method thereof according to the first embodiment of the invention, at least the following advantageous effects (1) to (4) can be obtained.

(1) As the temperature of the LSI rises from room temperature to higher temperatures (e.g. about 200° C.), the mobility of electrons, which are carriers, can be improved.

As has been described above, when the operation heat, which occurs when the nMOS transistor is operated, is conducted to the first element isolation insulation film 11-1, the first element isolation insulation film 11-1 contracts in accordance with its own negative expansion coefficient. Accordingly, a tensile stress TS occurs in the first element isolation insulation layer 11-1 along the channel length direction. As a result, the tensile stress can be applied to the channel region CH along the channel length direction.

It is known that in the case of the nMOS transistor, if the tensile stress is applied to the channel region in the channel length direction, the mobility of electrons is enhanced. Thus, even in the case where the temperature of the semiconductor substrate 12, etc. rises up to high temperatures, the mobility of electrons of the nMOS transistor can be improved.

In addition, since the tensile stress TS becomes higher as the temperature rises, the effect of the improvement in mobility of electrons is more conspicuous as the temperature becomes higher.

Moreover, since the volume of the first element isolation insulation layer 11-1 decreases in proportion to the rise in temperature, the tensile stress that is proportional to the rise in temperature can be applied to the channel region CH.

Hence, even in the case where the temperature of the LSI, or the like, including the nMOS transistor rises and there occurs a more intensified thermal disturbance of silicon, etc., a decrease in mobility of electrons can be prevented. As a result, under the circumstances in which the temperature of the LSI, etc. increases due to microfabrication of transistors in recent years, the degradation in characteristics of transistors can very advantageously be prevented.

In the case of the present embodiment, parts of the contact wiring lines SC and DC are provided on the fringe portions 20 of the first element isolation insulation films 11-1. Thus, also because the operation heat occurring in the contact wiring lines SC and DC is directly conducted to the first element isolation insulation films 11-1, the mobility of electrons can advantageously be improved.

(2) The optimal mobility of electrons of the nMOS transistor can be selected.

The magnitude of the tensile stress TS that is applied to the channel region CH increases in proportion to, e.g. the volume of the first element isolation insulation film 11-1.

Thus, the optimal mobility of electrons of the nMOS transistor can advantageously be selected by selecting, for example, when the silicon oxide film 21 is formed (FIG. 6), the depth of the trench for element isolation and controlling the volume of the silicon oxide film 21 that is buried in the trench, thereby selecting the optimal volume, for instance.

(3) Since the expansion coefficient of the first element isolation insulation film 11-1 can be controlled by properly selecting the heat treatment process, the negative expansion coefficient that is optimal for the actual device can be selected.

As shown in FIG. 11, the first element isolation insulation film 11-1 has two temperature regions, that is, the temperature region indicated by the solid line 31 where the crystal nuclei 25 are formed, and the temperature region indicated by the solid line 32 where the crystal nuclei 25 are grown. Accordingly, for example, if a heat treatment process is performed at low temperatures in the temperature region indicated by the solid line 31, and a heat treatment process is performed at the temperature T3, at which the growth rate of crystal nuclei is highest, in the temperature region indicated by the solid line 32, the first element isolation insulation film 11-1 with a relatively low expansion coefficient can be formed.

As has been described above, since various combinations of the temperatures (e.g. T2, T3) of the temperature regions indicated by the solid lines 31 and 32 and the time periods (e.g. Δt2, Δt3) can be selected at the time of performing the heat treatment process (FIG. 8 to FIG. 10), the crystal lines 19 and amorphous matrix layer 18 can be formed with various densities and sizes. Therefore, advantageously, the margin of the expansion coefficient can be increased, and the first element isolation insulation film 11-1 having a target expansion coefficient can easily be formed.

In addition, at the time of performing the ion implantation process (FIG. 7), the necessary expansion coefficient can be controlled by selecting the kind, composition and dosage of the crystal seeds 23.

As described above, even if the composition, etc. are the same, optimal conditions can be variously selected at the time of the heat treatment process (FIG. 8 to FIG. 10) or the ion implantation process (FIG. 7), and the expansion coefficient can be controlled in a wide range according to purposes.

(3) To be more specific, if the temperatures T2 and T3, and the time Δt2>time Δt3, are selected, it is possible to form the first element isolation insulation film 11-1 which has a large negative expansion coefficient and can apply a large tensile stress TS.

One aspect of the insulation layer, which functions to apply a greater tensile stress to the channel region CH, is that the insulation layer has a higher negative expansion coefficient. To achieve this, it is desirable that the crystal lines 19 be closely formed with a higher density. If the time Δt2 is increased, the density of the crystal nuclei can be increased, and if the time Δt3 is increased, each crystal nucleus 25 can be largely grown and a larger crystal line 19 can be formed.

Accordingly, in the case where the temperatures T2 and T3 are selected as in the present embodiment, both the temperatures T2 and T3 are temperatures at which the formation rate and growth rate of crystal nuclei take the maximum values (FIG. 11). Thus, by making the time Δt2 greater than the time Δt3 (time Δt2>time Δt3), the first element isolation insulation film 11-1 of glass ceramics, in which the crystal lines 19 are closely formed at high density, can be formed. If the time Δt2 is too short, the density of crystal nuclei 25 decreases, and crystal lines 19 cannot be formed at high density. On the other hand, if the time Δt3 is too long, each crystal nuclei 25 grows too large and a crack may occur due to stress.

Thus, the ratio of crystal lines 19 in the first element isolation insulation film 11-1 can be made greater than the ratio of amorphous matrix layer 18 in the first element isolation insulation film 11-1. As a result, advantageously, the expansion coefficient of the whole first element isolation insulation film 11-1 can be made negative, and the negative expansion coefficient can be made higher.

(4) The growth of crystal nuclei 25 can be made uniform, and the tensile stress TS, which is applied by the first element isolation insulation film 11-1, can be made uniform.

By increasing the rate α2 as high as possible, the temperature of the amorphous matrix layer 18 can be made to quickly reach the temperature T3 at which the crystal nucleus 25 grows at the highest rate, the non-uniformity in temperature can be prevented, and the time at which each crystal nucleus 25 is grown can be made uniform. Therefore, advantageously, the crystal nuclei 25 can be uniformly grown, the grain sizes of the crystal lines 19 can be made uniform, and the tensile stress TS, which is applied by the first element isolation insulation film 11-1, can be made uniform.

### [Modification (Another Example of the Method of Manufacturing the First Element Isolation Insulation Film)]

Next, referring to FIG. 12 to FIG. 14, a description is given of a semiconductor device according to a modification of the embodiment and a manufacturing method thereof. A description of parts common to those of the first embodiment is omitted here.

### Structure Example and the Application of Stress at Time of Driving Operation

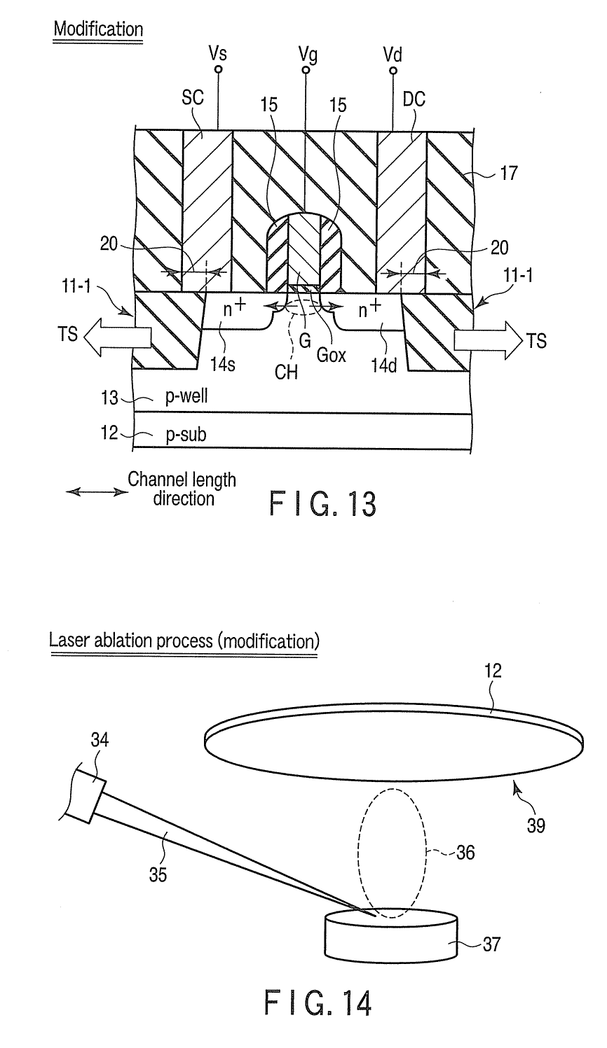

To begin with, referring to FIG. 12 and FIG. 13, a description is given of a structure example of a semiconductor device according to a modification of the embodiment and the application of stress at a time of a driving operation.

As shown in FIG. 12 and FIG. 13, the semiconductor device according to the modification differs from the semiconductor device of the above-described first embodiment in that the first element isolation insulation film 11-1 is formed of a HfW₂O₈ layer having a negative expansion coefficient. The HfW₂O₈ layer has a negative expansion coefficient of, e.g. about −10×10⁻⁶/K in a range between room temperature and about 800 K.

When the temperature rises due to, e.g. the operation heat when the nMOS transistor operates, the HfW₂O₈ layer 11-1 contracts and a tensile stress TS occurs in the channel region CH along the channel length direction. As a result, the tensile stress along the channel length direction can be applied to the channel region CH, and the mobility of electrons that are carriers can be enhanced.

Furthermore, the expansion coefficient of the HfW₂O₈ layer 11-1 varies from about room temperature, and varies in a wide temperature range up to about 800 K. Therefore, advantageously, this modification is widely adaptive to the temperature environment in which the device operates. It is possible to adopt, where necessary, the structure in which the HfW₂O₈ layer 11-1 is applied to the first element isolation insulation film 11-1.

As regards the other respects in structure and operation, the present modification is the same as the first embodiment.

### <Manufacturing Method>

Next, referring to FIG. 14, a description is given of a method of manufacturing the semiconductor device according to the embodiment.

To start with, a chemical reaction is caused to occur by putting an aqueous solution of HfOCl₂·6H₂O in ammonium solution of H₂WO₄, and HfW₂O₈ of the reactant is produced. The obtained HfW₂O₈ is dried, and heated up to about 1200° C. at a rate of 600° C./h. The HfW₂O₈ is kept at this temperature for about two hours, and HfW₂O₈ powder is formed (not shown).

Then, as shown in FIG. 14, the HfW₂O₈ powder is sintered, and a ceramics target 37 in a pellet form is prepared.

Subsequently, a laser beam 35, which is emitted from a light source 34, is radiated on the target 37 by a laser ablation method, and the target 37 is heated. Thereby, the HfW₂O₈ powder in the target 37 is evaporated in a plume 36.

The HfW₂O₈ powder in the plume 36 is deposited by evaporation on an element isolation region 39 of the nMOS transistor of the semiconductor substrate 12. Thus, the first element isolation insulation film 11-1 can be formed of the HfW₂O₈ layer.

Thereafter, using the same process as in the first embodiment, the semiconductor device according to the modification is fabricated.

According to the above-described manufacturing method, the same advantageous effects as in the first embodiment can be obtained. Furthermore, in the manufacturing method of the semiconductor device according to the modification, when the HfW₂O₈ powder is deposited by evaporation on the element isolation region 39 of the nMOS transistor of the semiconductor substrate 12, the temperature of the semiconductor substrate 12 can be lowered to, e.g. about 400° C.

Thus, the influence on an implantation profile, for instance, is small, and high-performance devices can very advantageously be fabricated.

Moreover, the molecules and atoms of HfW₂O₈, which are evaporated in the plume 36 from the target 37, are not merely evaporated but have very high kinetic energy (e.g. about 1,000,000,000° C. in terms of temperatures). Thus, even if the composition is the same, the HfW₂O₈ layer 11-1, which is deposited by evaporation on the semiconductor substrate 12, can have physical properties, such as a higher negative expansion coefficient, which cannot be obtained by other methods. According to the present method, atoms can be stacked layer by layer, and the controllability can advantageously be enhanced.

Not only by the above-described laser ablation method, but also by a sputtering method with the ceramics target 37 being used as a target, for instance, the HfW₂O₈ layer 11-1 can be formed on the element isolation region 39 of the nMOS transistor on the semiconductor substrate 12.

Besides, in the present modification, the HfW₂O₈ layer has been described as an example of the first element isolation insulation film 11-1. However, instead of the HfW₂O₈ layer, a ZrW₂O₈ layer or an Nb₂O₅ layer, for instance, is usable. In the case where the ZrW₂O₈ layer is used, the first element isolation insulation film 11-1 has a negative expansion coefficient of about −10×10⁻⁶/K, for example, in the range from room temperature to about 1200° C.

### SECOND EMBODIMENT

### An Example in which the Invention is Applied to a pMOS Transistor

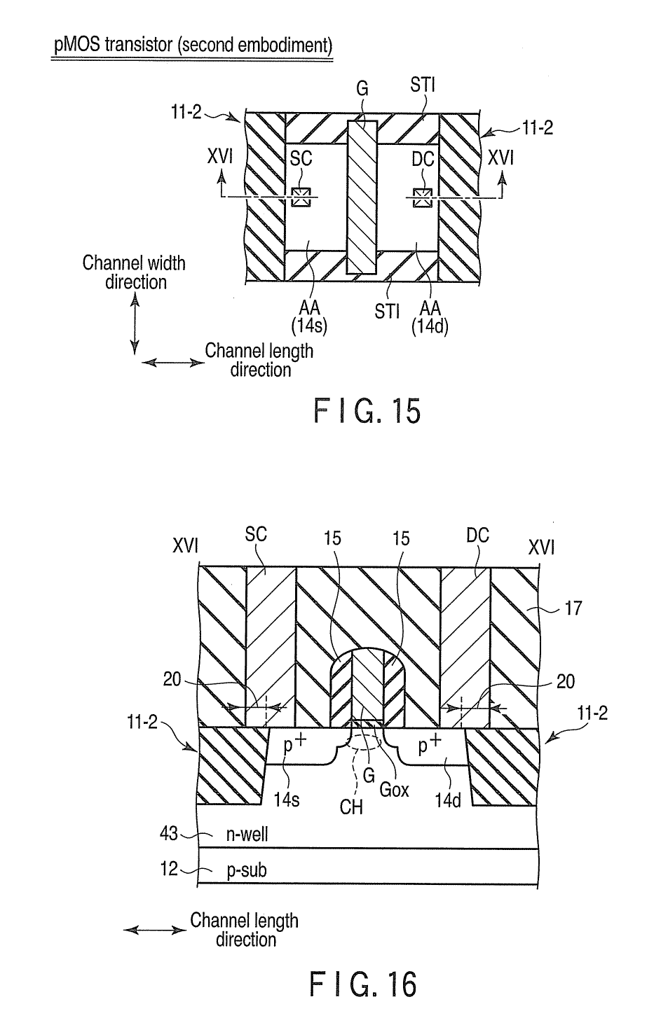

Next, referring to FIG. 15 to FIG. 18, a description is given of a semiconductor device according to a second embodiment of the invention. The second embodiment relates to an example in which the invention is applied to a pMOS transistor. A description of parts common to those of the first embodiment is omitted here.

### Structure Example

To begin with, referring to FIG. 15, a description is given of a structure example of the semiconductor device according to the second embodiment. As shown in FIG. 15, the semiconductor device (pMOS transistor) according to the present embodiment is disposed in an element region of the semiconductor substrate (p-sub) 12. In an element isolation region of the semiconductor substrate 12, a second element isolation insulation film 11-2 and an element isolation insulation film STI (Shallow Trench Isolation) are disposed so as to surround the pMOS transistor.

The pMOS transistor includes a gate insulation film Gox provided on an n-well 43 which is formed in the semiconductor substrate 12, a gate electrode G provided on the gate insulation film Gox, a source 14s and a drain 14d provided spaced apart in the semiconductor substrate 12 in a manner to sandwich the gate electrode G, spacers 15 provided on side walls of the gate electrode G, and contact wiring lines SC and DC. This pMOS transistor is an insulated-gate field-effect transistor having holes, which are doped p-type impurities, as carriers.

The gate insulation film Gox is formed of, for example, a silicon oxide film (SiO₂) by a thermal oxidation method.

The gate electrode G is formed of, for example, polysilicon (poly-Si).

The source 14s and drain 14d (p+ layer) are formed such that p-type impurities, such as gallium (Ga) or indium (In), are doped, for example, by ion implantation and are thermally diffused. The doped p-type impurities release holes serving as carriers.

The spacers 15 are formed of, e.g. a silicon nitride (SiN) film. The contact wiring lines SC and DC are provided in an interlayer insulation film 17 on the source 14s and drain 14d. Parts of the contact wiring lines SC and DC are provided on fringe portions 20 of the second element isolation insulation films 11-2.

The second element isolation insulation film 11-2 is buried in a trench in the element isolation region of the semiconductor substrate 12, has a positive expansion coefficient, and applies a compressive stress to the pMOS transistor by operation heat.

The second element isolation insulation film 11-2 has a positive expansion coefficient (positive expansion factor) [ΔV/V/ΔT] (V: volume, T: temperature, ΔT: volume variation). The positive expansion coefficient, in this context, refers to a ratio at which the volume increases in accordance with an increase in temperature. The above-described compressive stress in this embodiment is, e.g. about several to several-ten GPa. The second element isolation insulation film 11-2 in this embodiment is formed of a silicon oxide film (SiO₂ film). Most of substances expand in accordance with an increase in temperature, and thus have positive expansion coefficients. Accordingly, there are many choices of materials having positive expansion coefficients. Any material, which should preferably have a high expansion coefficient and does not adversely affect device performances, is applicable as a buried material of the second element isolation insulation film 11-2. Taking into account the fact that the buried material of the existing element isolation insulation film STI is the silicon oxide film (SiO₂ film), it is considered that it is the best solution to add to the silicon oxide film (SiO₂ film) such a composition as to increase the expansion coefficient. Other modes of the buried material may include an amorphous mode and a mode in which the composition of the above-described glass ceramics is varied. Aside from the silicon oxide film (SiO₂ film), use may be made of buried materials with positive expansion coefficients, such as an aluminum oxide film (Al₂O₃ film) and an aluminum nitride film (AlN film), which have large thermal expansion coefficients and large elastic coefficients.

### <Application of Stress at Time of Driving Operation>

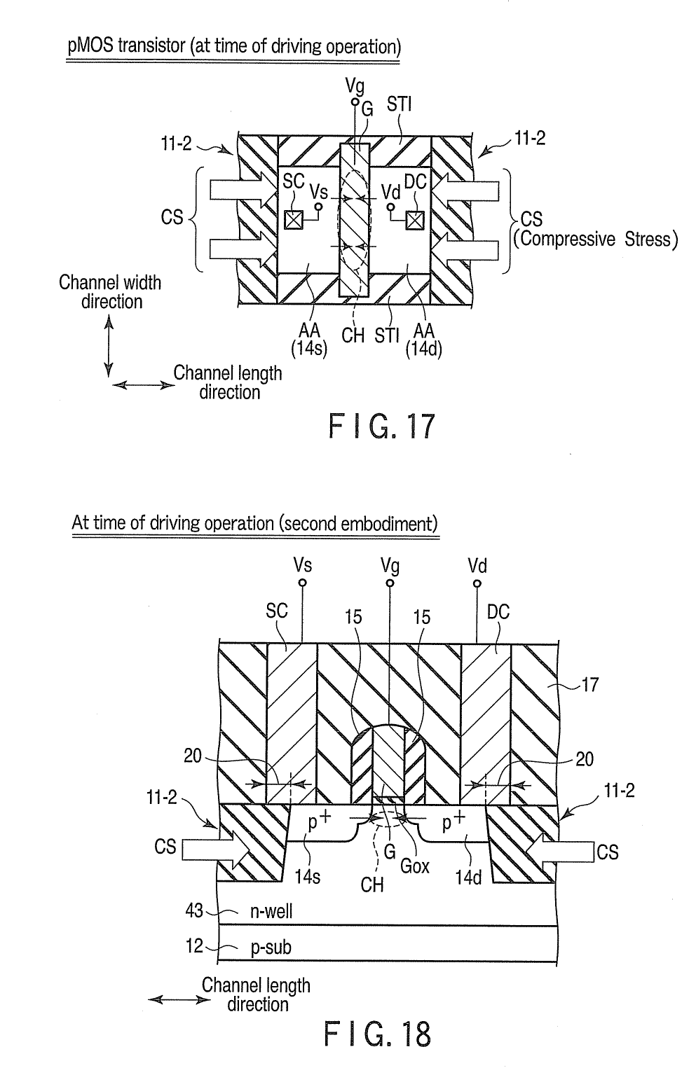

Next, referring to FIG. 17 and FIG. 18, a description is given of the application of stress at the time of the driving operation of the semiconductor device according to the second embodiment of the invention.

As shown in FIG. 17 and FIG. 18, in the above-described structure, when the pMOS transistor is driven, a source voltage Vs, a drain voltage Vd and a predetermined gate voltage Vg are applied. Then, holes, which are carriers, move in the channel CH which is formed in the semiconductor substrate 43 below the gate electrode G. Thereby, the holes flow between the source 14s and drain 14d, and a switching operation is performed. At this time, operation heat is produced by the application voltage, such as the drain voltage Vd, and the switching current.

If the operation heat is conducted to the second element isolation insulation layer 11-2, the second element isolation insulation layer 11-2 expands in accordance with its own positive expansion coefficient. Accordingly, a compressive stress CS occurs in the second element isolation insulation layer 11-2 along the channel length direction. As a result, the compressive stress is applied to the channel region CH along the channel length direction. The compressive stress CS is, e.g. about several to several-ten GPa.

Hence, even in the case where the temperature of the semiconductor substrate 12, for instance, rises to high temperatures, the mobility of holes, which are carriers of the pMOS transistor, can be increased.

In the case of this embodiment, parts of the contact wiring lines SC and DC are provided on the fringe portions 20 of the second element isolation insulation films 11-2. Thus, also because the operation heat occurring in the contact wiring lines SC and DC is directly conducted to the second element isolation insulation films 11-2, the mobility of holes can advantageously be improved.

Needless to say, the same operation can be obtained, not only by the above-described operation heat occurring due to the driving operation of the pMOS transistor, but also by the operation heat, in a broader sense, occurring when the LSI including this pMOS transistor is operated.

### <Manufacturing Method>

Next, a description is given of a method of manufacturing the semiconductor device according to the second embodiment of the invention.

Although not shown, to begin with, n-type impurities, such as gallium (Ga), are doped in the semiconductor substrate 12, and an n-well 43 is formed.

Then, a trench for element isolation is formed in an element isolation region of the semiconductor substrate 12, for example, by using RIE. A silicon oxide (SiO₂) film having a positive expansion coefficient, for instance, is buried in the trench by, e.g. CVD, and a second element isolation insulation film 11-2 is formed.

As has been described above, most of substances expand in accordance with an increase in temperature, and thus have positive expansion coefficients. Accordingly, there are many choices of materials having positive expansion coefficients. Any material, which should preferably have a high expansion coefficient and does not adversely affect device performances, is applicable as a buried material of the second element isolation insulation film 11-2. Taking into account the fact that the buried material of the existing element isolation insulation film STI is the silicon oxide film (SiO₂ film), it is considered that it is the best solution to add to the silicon oxide film (SiO₂ film) such a composition as to increase the expansion coefficient, as in the present embodiment. Other modes of the buried material may include an amorphous mode and a mode in which the composition of the above-described glass ceramics is varied. Aside from the silicon oxide film (SiO₂ film), use may be made of buried materials with positive expansion coefficients, such as an aluminum oxide film (Al₂O₃ film) and an aluminum nitride film (AlN film), which have large thermal expansion coefficients and large elastic coefficients.

Subsequently, by using substantially the same fabrication process as in the first embodiment, the semiconductor device according to the present embodiment is formed.

### <Advantageous Effects>

With the semiconductor device and the manufacturing method thereof according to the present second embodiment of the invention, at least the same advantageous effects as described above can be obtained. In addition, at least the following advantageous effect (5) can be obtained.

(5) As the temperature of the LSI rises from room temperature to higher temperatures (e.g. about 200° C.), the mobility of holes, which are carriers, can be increased.

As has been described above, when the operation heat, which occurs when the pMOS transistor is operated, is conducted to the second element isolation insulation film 11-2, the second element isolation insulation film 11-2 expands in accordance with its own positive expansion coefficient. Accordingly, a compressive stress CS occurs in the second element isolation insulation layer 11-2 along the channel length direction. As a result, the compressive stress can be applied to the channel region CH along the channel length direction.

Thus, even in the case where the temperature of the semiconductor substrate 12, for instance, rises up to high temperatures, the mobility of holes of the pMOS transistor can be improved.

In addition, since the compressive stress CS becomes higher as the temperature rises, the effect of the improvement in mobility of holes is more conspicuous as the temperature becomes higher.

Moreover, since the volume of the second element isolation insulation layer expands in proportion to the rise in temperature, the compressive stress that is proportional to the rise in temperature can be applied to the channel region CH. Hence, even in the case where the temperature of the LSI, for instance, including the pMOS transistor rises and there occurs a more intensified thermal disturbance of silicon, etc., a decrease in mobility of holes can be prevented. As a result, under the circumstances in which the temperature of the LSI, for instance, increases due to microfabrication of transistors in recent years, the degradation in characteristics of transistors can very advantageously be prevented.

### THIRD EMBODIMENT

### An Example of Application of Biaxial Stress (pMOS Transistor)

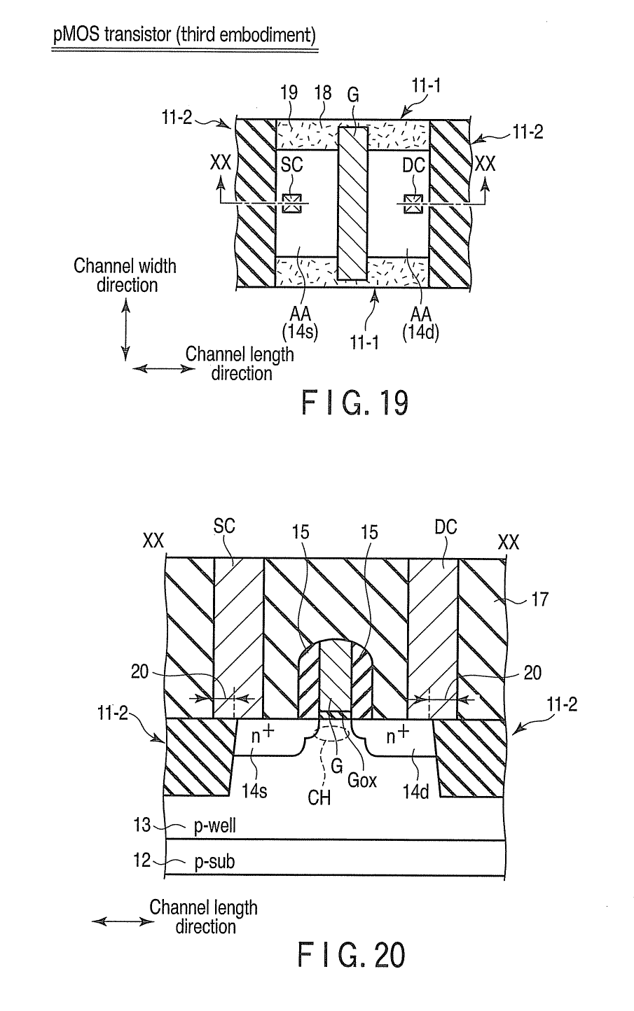

Next, referring to FIG. 19 to FIG. 22, a description is given of a semiconductor device according to a third embodiment of the invention. The third embodiment relates to an example in which stress is applied to the channel region of a pMOS transistor in two axial directions. A detailed description of parts common to those of the second embodiment is omitted here.

### Structure Example

The semiconductor device of the third embodiment differs from that of the second embodiment in that, as shown in FIG. 19 and FIG. 20, a first element isolation insulation film 11-1 having a negative expansion coefficient is also disposed along the channel length direction in the semiconductor substrate 12 in the element isolation insulation film in a manner to surround the pMOS transistor. In other words, in the present embodiment, the first element isolation insulation film 11-1 having a negative expansion coefficient is disposed along the channel length direction and the second element isolation insulation film 11-2 having a positive expansion coefficient is disposed along the channel width direction in the semiconductor substrate 12 in the element isolation insulation film, such that the pMOS transistor are surrounded by the first element isolation insulation film 11-1 and the second element isolation insulation film 11-2.

The first element isolation insulation film 11-1, as in the preceding embodiment, is formed of a glass ceramics layer including an amorphous matrix layer 18 and crystal lines 19 dispersed in the amorphous matrix layer 18. The second element isolation insulation film 11-2 is formed of, e.g. a silicon oxide film.

### <Application of Stress at Time of Driving Operation>

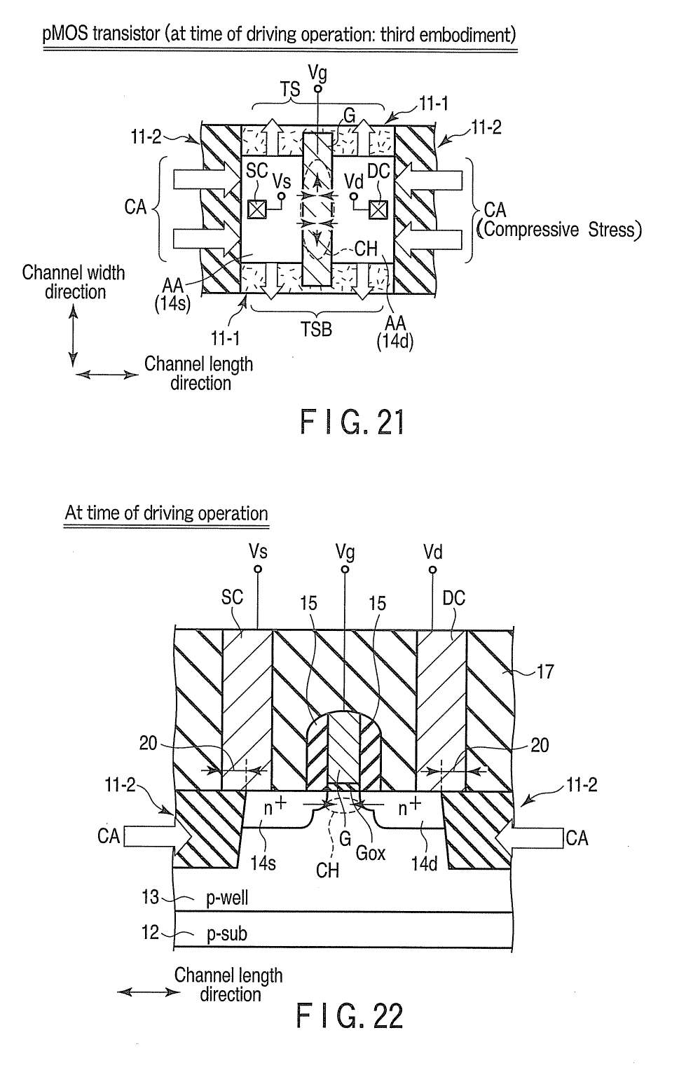

Next, referring to FIG. 21 and FIG. 22, a description is given of the application of stress at the time of the driving operation of the semiconductor device according to the third embodiment.

As shown in FIG. 21 and FIG. 22, in the above-described structure, when the pMOS transistor is driven, a source voltage Vs, a drain voltage Vd and a predetermined gate voltage Vg are applied. Then, holes, which are carriers, move in the channel CH which is formed in the semiconductor substrate 12 below the gate electrode G. Thereby, the holes flow between the source 14s and drain 14d, and a switching operation is performed. At this time, operation heat is produced by the application voltage, such as the drain voltage Vd, and the switching current.

If the operation heat is conducted to the first and second element isolation insulation layer 11-1 and 11-2, the first element isolation insulation layer 11-1 contracts in accordance with its own negative expansion coefficient and the second element isolation insulation layer 11-2 expands in accordance with its own positive expansion coefficient. Accordingly, a tensile stress TS occurs in the first element isolation insulation layer 11-1 along the channel width direction, and a compressive stress CA occurs in the second element isolation insulation layer 11-2 along the channel length direction.

Thus, the compressive force CA and tensile stress TS occur at the same time in the channel length direction and channel width direction. As a result, a stronger compressive stress and a stronger tensile stress are applied at the same time to the channel region CH in the two axial directions that are the channel length direction and channel width direction.

Therefore, even in the case where the temperature of the semiconductor substrate 12, etc. rises up to high temperatures, the mobility of holes, which are carriers of the pMOS transistor, can advantageously be further improved.

### FOURTH EMBODIMENT

### An Example of Application of Tensile Stress in Two Axial Directions of nMOS Transistor (or pMOS Transistor)

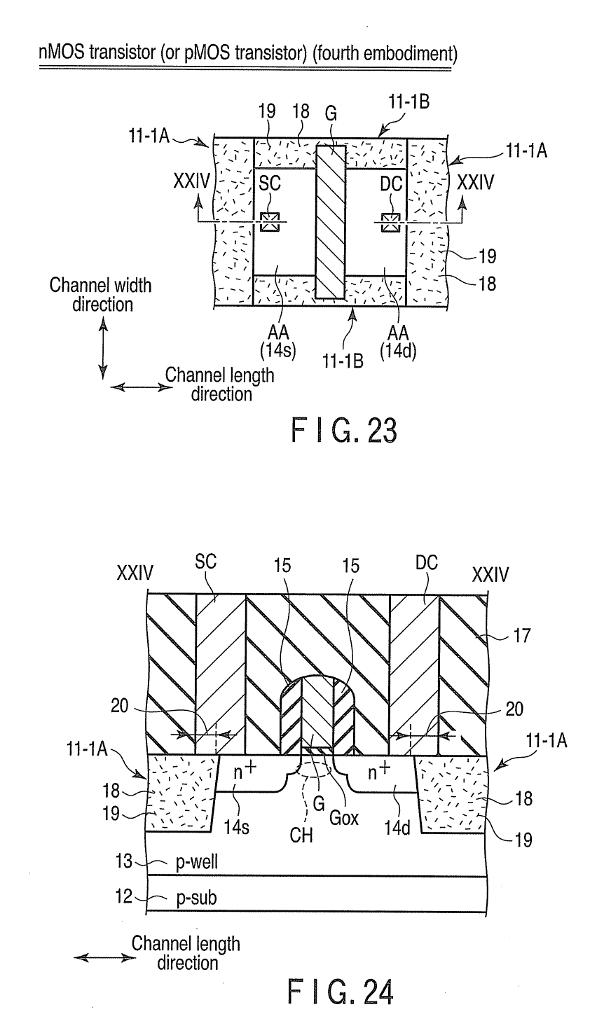

Next, referring to FIG. 23 to FIG. 26, a description is given of a semiconductor device according to a fourth embodiment of the invention. The fourth embodiment relates to an example in which tensile stress is applied in two axial directions of an nMOS transistor (or pMOS transistor). A detailed description of parts common to those of the above-described first embodiment is omitted here.

As shown in FIG. 23 and FIG. 24, the semiconductor device of the fourth embodiment differs from that of the first embodiment in that a first element isolation insulation film 11-1B having a negative expansion coefficient is also disposed in the channel length direction in the semiconductor substrate 12 in the element isolation insulation region in a manner to surround the nMOS transistor. In other words, in the present embodiment, the first element isolation insulation films 11-1A and 11-1B having negative expansion coefficients are disposed in the channel width direction and the channel length direction in the semiconductor substrate 12 in the element isolation insulation region in a manner to surround the nMOS transistor.

The first element isolation insulation film 11-1B has the same structure as the first element isolation insulation film 11-1A. Specifically, the first element isolation insulation film 11-1B is formed of a glass ceramics layer including an amorphous matrix layer 18 and crystal lines 19 dispersed in the amorphous matrix layer 18.

### <Application of Stress at Time of Driving Operation>

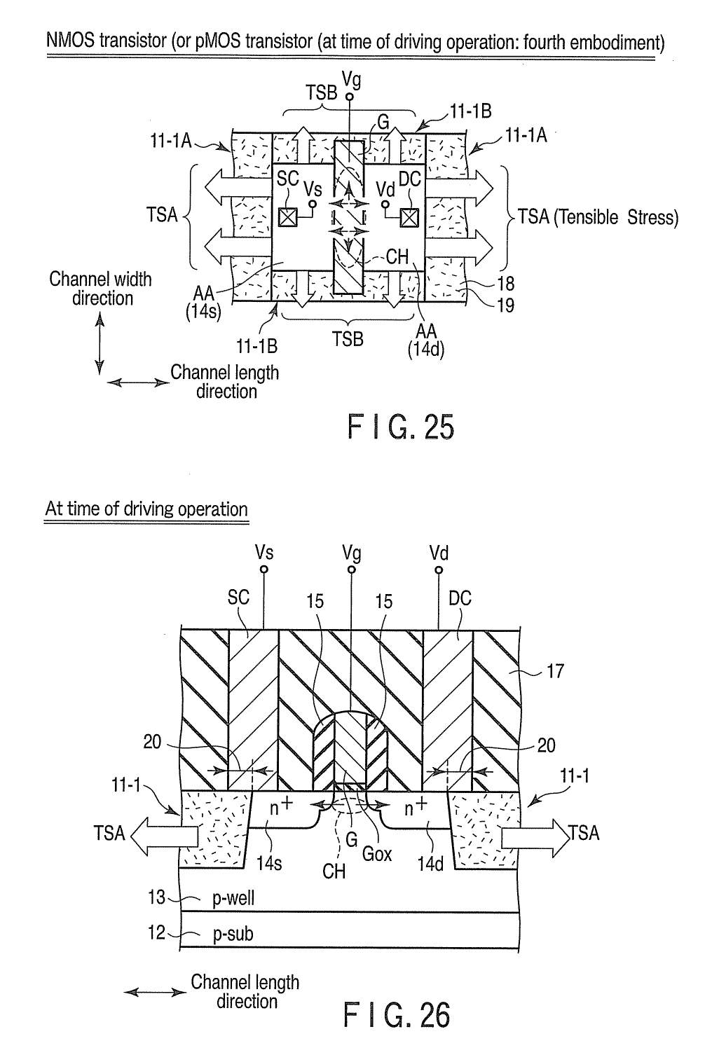

Next, referring to FIG. 25 and FIG. 26, a description is given of the application of stress at the time of the driving operation of the semiconductor device according to the fourth embodiment.

As shown in FIG. 25 and FIG. 26, in the above-described structure, when the nMOS transistor is driven, a source voltage Vs, a drain voltage Vd and a predetermined gate voltage Vg are applied. Then, electrons, which are carriers, move in the channel CH which is formed in the semiconductor substrate 12 below the gate electrode G. Thereby, the electrons flow between the source 14s and drain 14d, and a switching operation is performed. At this time, operation heat is produced by the application voltage, such as the drain voltage Vd, and the switching current.

If the operation heat is conducted to the first element isolation insulation layers 11-1A and 11-1B, the first element isolation insulation layers 11-1A and 11-1B contract in accordance with their own negative expansion coefficients. Accordingly, tensile stresses TSA and TSB occur at the same time in the first element isolation insulation layers 11-1A and 11-1B in two axial directions that are the channel length direction and the channel width direction. As a result, a stronger tensile stress is applied at the same time to the channel region CH in the two axial directions that are the channel length direction and the channel width direction. Each of the tensile stresses TSA and TSB is, e.g. about 80 to 100 GPa. Therefore, even in the case where the temperature of the semiconductor substrate 12, etc. rises up to high temperatures, the mobility of electrons, which are carriers of the nMOS transistor, can advantageously be further improved.

### <Advantageous Effects>

The semiconductor device of the fourth embodiment differs from that of the first embodiment in that the first element isolation insulation film 11-1B having the negative expansion coefficient is disposed in the channel length direction in the element isolation insulation region in a manner to surround the nMOS transistor. In other words, in the present embodiment, the first element isolation insulation films 11-1A and 11-1B having negative expansion coefficients are disposed in the channel width direction and the channel length direction in the element isolation insulation region in a manner to surround the nMOS transistor.

Thus, in the above-described structure, when the nMOS transistor is driven, the source voltage Vs, drain voltage Vd and predetermined gate voltage Vg are applied. Then, electrons, which are carriers, move in the channel CH which is formed in the semiconductor substrate 12 below the gate electrode G. Thereby, the electrons flow between the source 14s and drain 14d, and a switching operation is performed. At this time, operation heat is produced by the application voltage, such as the drain voltage Vd, and the switching current. If the operation heat is conducted to the first element isolation insulation layers 11-1A and 11-1B, the first element isolation insulation layers 11-1A and 11-1B contract in accordance with their own negative expansion coefficients. Accordingly, tensile stresses TSA and TSB occur at the same time in the first element isolation insulation layers 11-1A and 11-1B in two axial directions that are the channel length direction and the channel width direction. As a result, a stronger tensile stress is applied at the same time to the channel region CH in the two axial directions that are the channel length direction and the channel width direction. Each of the tensile stresses TSA and TSB is, e.g. about 80 to 100 GPa.

Hence, even in the case where the temperature of the semiconductor substrate 12, etc. rises up to high temperatures, the mobility of electrons, which are carriers of the nMOS transistor, can advantageously be further improved.

In the present embodiment, the n-type MOS transistor, i.e. nMOS transistor, has been exemplified in the description of the advantageous effect that is obtained by applying at the same time the tensile stresses to the channel region CH in the two perpendicular axial directions. The type of the MOS transistor, however, is not limited to the n-type MOS transistor. The mobility of holes, which are carriers of a pMOS transistor, can be improved even in the case where the tensile stresses are applied at the same time to the channel region CH of the pMOS transistor in the two perpendicular axial directions. This embodiment is also advantageous in that the conductivity type of the transistor is not limited.

It should suffice if the first element isolation insulation layers 11-1A and 11-1B have negative expansion coefficients. These first element isolation insulation layers 11-1A and 11-1B may be formed of different materials. In the case where the tensile stresses TSA and TSB are applied at the same time in the two perpendicular axial directions, as described above, the mobility of electrons can be improved. Therefore, the embodiment is very advantageous in that the mobility of electrons in the nMOS transistor can be improved.

### FIFTH EMBODIMENT

### An Example in which Uniaxial Stress is Applied to Plural N-Type and P-Type Transistors

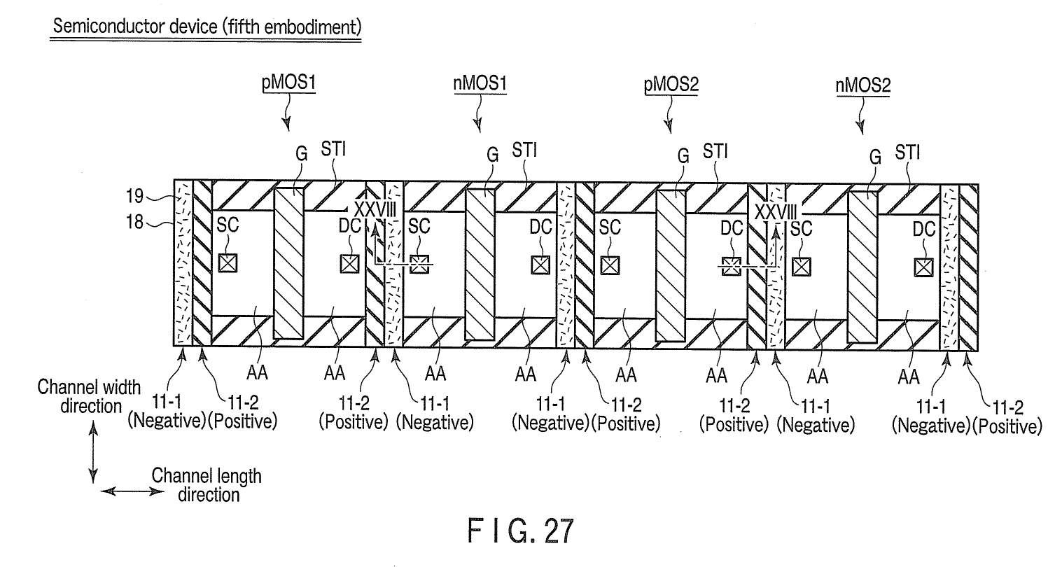

Next, referring to FIG. 27 to FIG. 30, a description is given of a semiconductor device according to a fifth embodiment of the invention. The fifth embodiment relates to an example in which stress in one axial direction is applied to a plurality of n-type and p-type transistors. A detailed description of parts common to those of the above-described first embodiment is omitted here.

### Structure Example

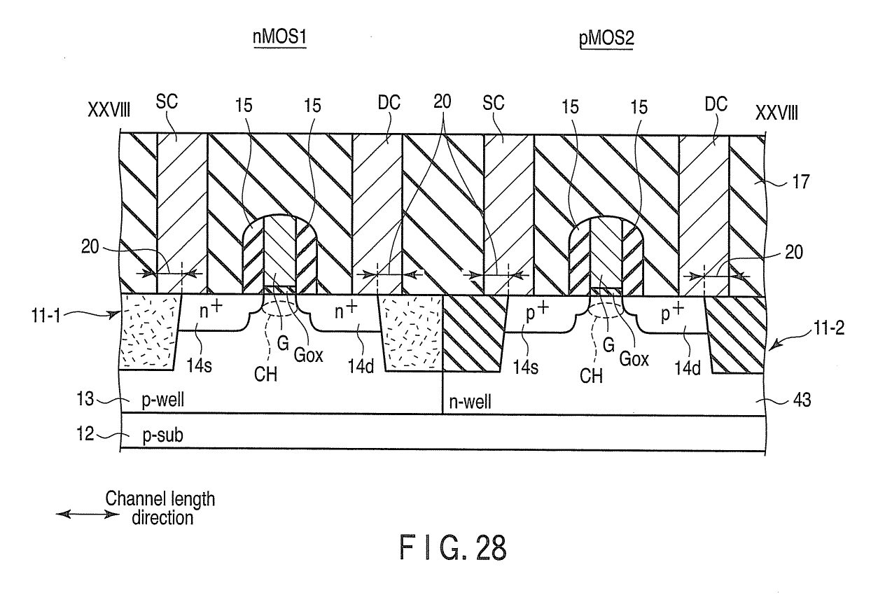

Referring to FIG. 27 and FIG. 28, a description is given of a structure example of a semiconductor device according to the present embodiment. As shown in FIG. 27 and FIG. 28, in the semiconductor device according to the fifth embodiment, nMOS transistors nMOS1 and nMOS2 according to the first embodiment and pMOS transistors pMOS1 and pMOS2 according to the second embodiment are alternately and adjacently arranged in the channel length direction.

First and second element isolation insulation films 11-1 and 11-2 are alternately and adjacently arranged in the channel length direction in the element isolation region in the semiconductor substrate 12. The first element isolation insulation film 11-1 has the negative expansion coefficient, as in the above-described case. The second element isolation insulation film 11-2 has the positive expansion coefficient, as in the above-described case.

### <Application of Stress at Time of Driving Operation>

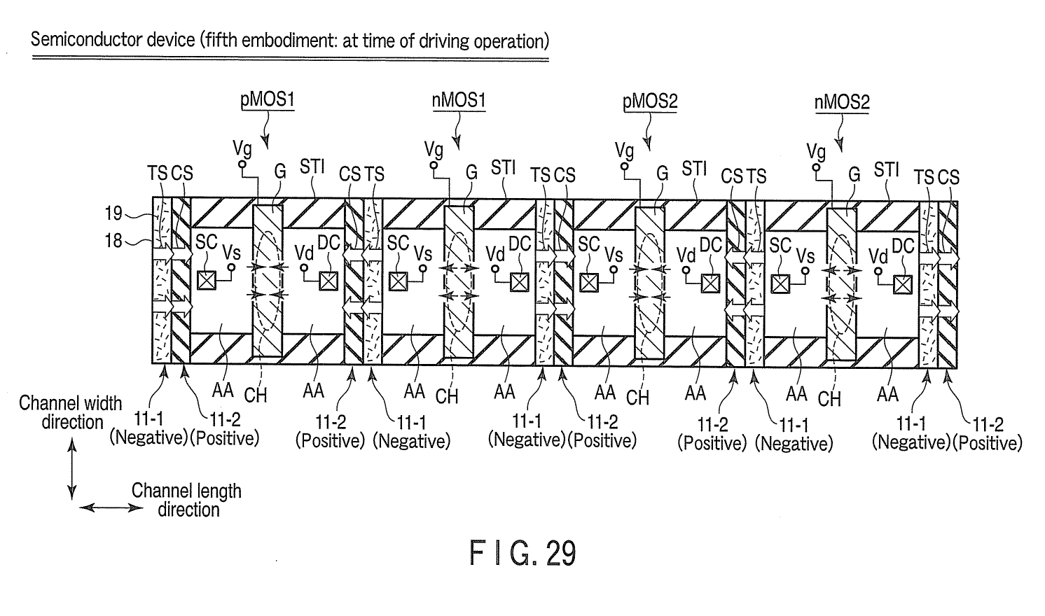

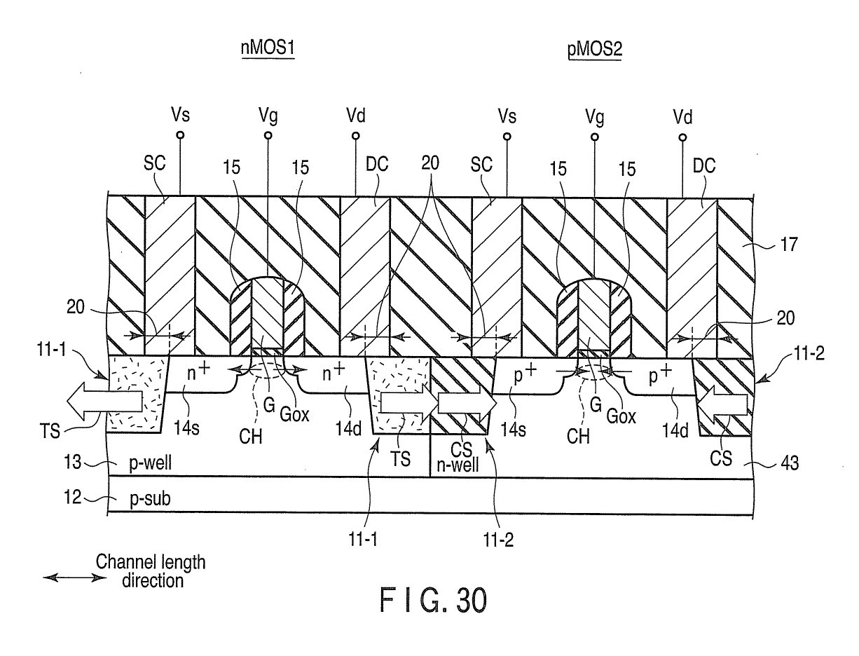

Next, referring to FIG. 29 and FIG. 30, a description is given of the application of stress at the time of the driving operation of the semiconductor device according to the fifth embodiment.

As shown in FIG. 29 and FIG. 30, in the above-described structure, when the transistors nMOS1, nMOS2, pMOS1 and pMOS2 are driven, a source voltage Vs, a drain voltage Vd and a predetermined gate voltage Vg are applied. Then, electrons and holes, which are carriers, move in the channel CH which is formed in the semiconductor substrate 12 below the gate electrode G. Thereby, the electrons and holes flow between the source 14s and drain 14d, and a switching operation is performed. At this time, operation heat is produced by the application voltage, such as the drain voltage Vd, and the switching current.

If the operation heat is conducted to the first and second element isolation insulation layer 11-1 and 11-2, the first element isolation insulation layer 11-1 contracts in accordance with its own negative expansion coefficient, and the second element isolation insulation layer 11-2 expands in accordance with its own positive expansion coefficient. Accordingly, a tensile stress TS occurs in the first element isolation insulation layer 11-1 along the channel length direction, and a compressive stress CS occurs in the second element isolation insulation layer 11-2 along the channel length direction. In this case, since the first and second element isolation insulation layer 11-1 and 11-2 are adjacently disposed, their tensile stress TS and compressive stress CS are mutually strengthened, and the tensile stress TS and compressive stress CS can be increased by the synergistic effect.

As a result, a greater tensile stress is applied in the channel length direction to the channel region CH of the nMOS transistor nMOS1, nMOS2, and a greater compressive stress is applied in the channel length direction to the channel region CH of the pMOS transistor pMOS1, pMOS2.

According to this embodiment, even in the case where the temperature of the semiconductor substrate 12, etc. rises up to high temperatures, the mobility of electrons, which are carriers of the nMOS transistor, and the mobility of holes, which are carriers of the pMOS transistor, can advantageously be improved at the same time.

### <Manufacturing Method>

The manufacturing method according to the fifth embodiment differs from that of the first embodiment in that while one of the first and second element isolation insulation films 11-1 and 11-2 is being formed, the region of the other element isolation insulation film is covered with a protection film or the like.

For example, while the first element isolation insulation film 11-1 of the nMOS transistor nMOS1, nMOS2 is being formed, a silicon nitride (Si₃N₄) film, for instance, is deposited by, e.g. CVD, on the formation region of the pMOS transistor pMOS1, pMOS2, thereby forming a protection film. Then, the first element isolation insulation film 11-1 is formed by using the same manufacturing process as in the first embodiment. Subsequently, the protection film is removed.

Following the above, a similar protection film is formed on the formation region of the nMOS transistor nMOS1, nMOS2. Using the same manufacturing process as in the second embodiment, the second element isolation insulation film 11-2 is formed. Then, using the same manufacturing process as described above, the transistors nMOS1, nMOS2, pMOS1 and pMOS2 are formed.

### SIXTH EMBODIMENT

### An Example in which Biaxial Stress is Applied to Plural N-Type and P-Type Transistors

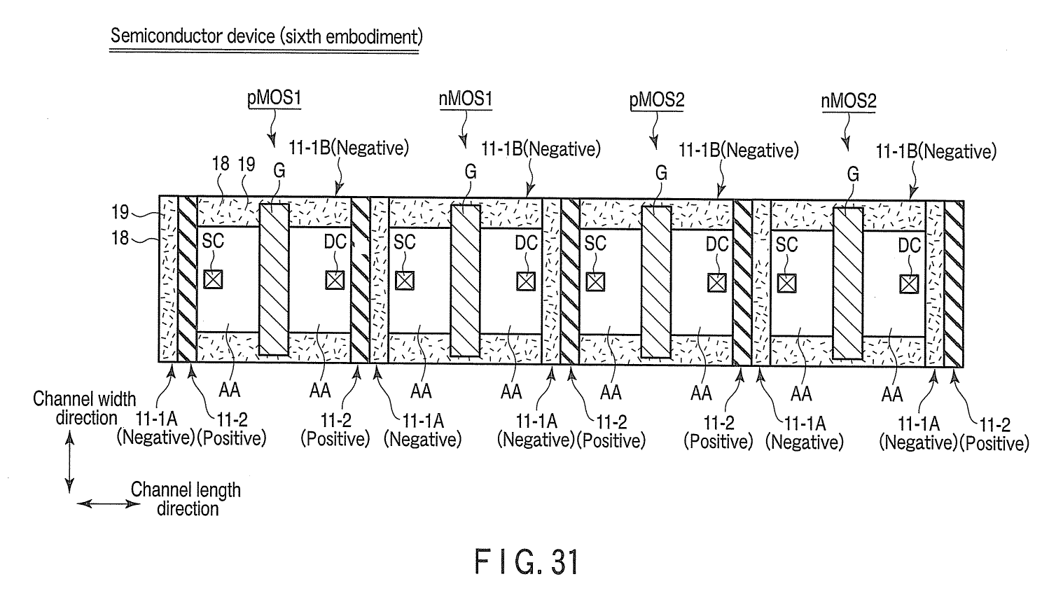

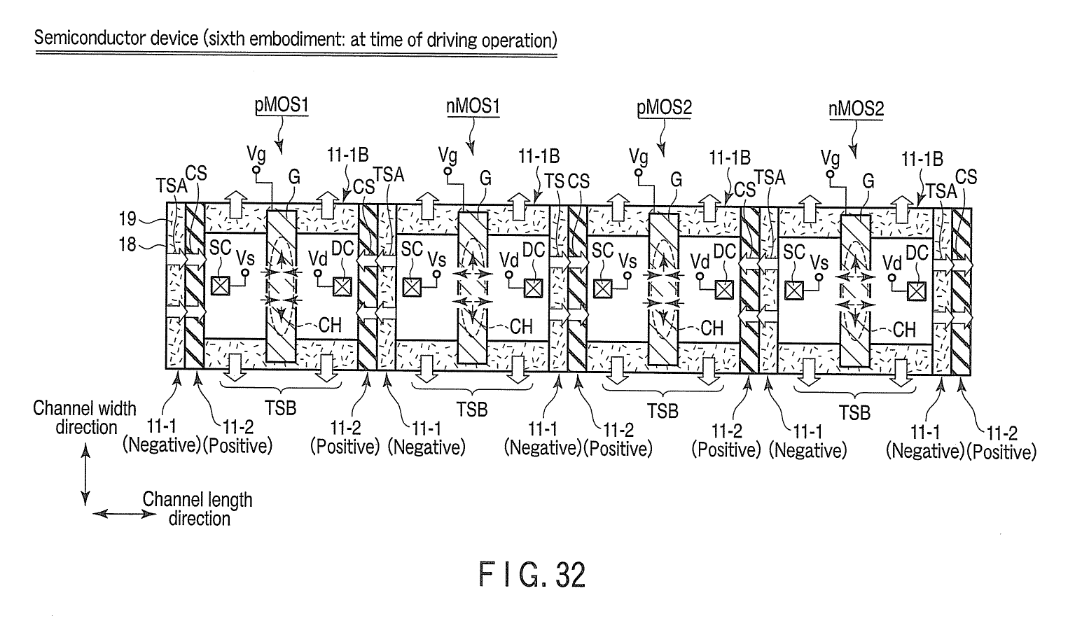

Next, referring to FIG. 31 and FIG. 32, a description is given of a semiconductor device according to a sixth embodiment of the invention. The sixth embodiment relates to an example in which stress in two axial directions is applied to a plurality of n-type and p-type transistors. A detailed description of parts common to those of the above-described fifth embodiment is omitted here.

### Structure Example

Referring to FIG. 31, a description is given of a structure example of the semiconductor device according to the present embodiment. As shown in FIG. 31, the semiconductor device of the sixth embodiment differs from that of the fifth embodiment in that a first element isolation insulation film 11-1B having a negative expansion coefficient is also disposed along the channel length direction in the semiconductor substrate 12 in the element isolation insulation region in a manner to surround the transistor nMOS1, nMOS2, pMOS1, pMOS2. In other words, the present embodiment differs from the fifth embodiment in that the first and second element isolation insulation film 11-1A, 11-1B and 11-2 are disposed in the channel width direction and the channel length direction in the semiconductor substrate 12 in the element isolation insulation region, such that the transistor nMOS1, nMOS2, pMOS1, pMOS2, is surrounded.

The first element isolation insulation film 11-1B has the same structure as the first element isolation insulation film 11-1A. Specifically, the second element isolation insulation film 11-1B is formed of a glass ceramics layer including an amorphous matrix layer 18 and crystal lines 19 dispersed in the amorphous matrix layer 18.

The first element isolation insulation films 11-1A and 11-1B have negative expansion coefficients, as in the above-described case. The second element isolation insulation film 11-2 has a positive expansion coefficient, as in the above-described case.

### <Application of Stress at Time of Driving Operation>

Next, referring to FIG. 32, a description is given of the application of stress at the time of the driving operation of the semiconductor device according to the sixth embodiment.

As shown in FIG. 32, in the above-described structure, when the transistors nMOS1, nMOS2, pMOS1 and pMOS2 are driven, a source voltage Vs, a drain voltage Vd and a predetermined gate voltage Vg are applied. Then, electrons and holes, which are carriers, move in the channel CH which is formed in the semiconductor substrate 12 below the gate electrode G. Thereby, the electrons and holes flow between the source 14s and drain 14d, and a switching operation is performed. At this time, operation heat is produced by the application voltage, such as the drain voltage Vd, and the switching current.

If the operation heat is conducted to the first and second element isolation insulation layer 11-1A, 11-1B and 11-2, the first element isolation insulation layers 11-1A and 11-1B contract in accordance with their own negative expansion coefficients, and the second element isolation insulation layer 11-2 expands in accordance with its own positive expansion coefficient. Accordingly, tensile stresses TSA and TSB occur in the first element isolation insulation layers 11-1A and 11-1B along the channel length direction and the channel width direction. A compressive stress CS occurs in the second element isolation insulation layer 11-2 along the channel length direction. In this case, since the first and second element isolation insulation layer 11-1A, 11-1B and 11-2 are adjacently disposed, their tensile stress TSA and compressive stress CS are mutually strengthened, and the tensile stress TSA and compressive stress CS can be increased by the synergistic effect.

As a result, a greater tensile stress along the channel length direction and a greater tensile stress along the channel width direction are applied at the same time in two axial directions to the channel region CH of the nMOS transistor nMOS1, nMOS2. Similarly, a greater compressive stress along the channel length direction and a greater tensile stress along the channel width direction are applied at the same time in two axial directions to the channel region CH of the pMOS transistor pMOS1, pMOS2.

According to this embodiment, even in the case where the temperature of the semiconductor substrate 12, etc. rises up to high temperatures, the mobility of electrons, which are carriers of the nMOS transistor, and the mobility of holes, which are carriers of the pMOS transistor, can advantageously be improved at the same time.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an insulated-gate field-effect transistor including a gate electrode provided on a semiconductor substrate, and a source and a drain provided spaced apart in the semiconductor substrate in a manner to sandwich the gate electrode, the insulated-gate field-effect transistor having electrons or holes as carriers; and
an element isolation insulation film having a negative expansion coefficient, which is disposed in the semiconductor substrate in an element isolation region along a channel width direction and a channel length direction in a manner to surround the insulated-gate field-effect transistor, the element isolation insulation film applying a tensile stress by operation heat to the insulated-gate field-effect transistor in two axial directions that are the channel width direction and the channel length direction.

2. The device of claim 1, further comprising a contact wiring line provided on the source or the drain, a portion of the contact wiring line being provided on a fringe of the element isolation insulation film.

3. The device of claim 1, wherein the element isolation insulation film includes a glass ceramics layer including an amorphous matrix layer and crystal lines dispersed in the amorphous matrix layer, or includes a HfW₂O₈ layer.

4. A semiconductor device comprising:
a first insulated-gate field-effect transistor including a gate electrode provided on a semiconductor substrate, and a source and a drain provided spaced apart in the semiconductor substrate in a manner to sandwich the gate electrode, the first insulated-gate field-effect transistor having electrons as carriers;
a second insulated-gate field-effect transistor including a gate electrode provided on the semiconductor substrate, and a source and a drain provided spaced apart in the semiconductor substrate in a manner to sandwich the gate electrode, the second insulated-gate field-effect transistor having holes as carriers;
a first element isolation insulation film having a negative expansion coefficient, which is buried in a trench in an element isolation region of the semiconductor substrate, the first element isolation insulation film applying a tensile stress by operation heat to the first insulated-gate field-effect transistor; and
a second element isolation insulation film having a positive expansion coefficient, which is buried in a trench in an element isolation region of the semiconductor substrate, the second element isolation insulation film applying a compressive stress by operation heat to the second insulated-gate field-effect transistor.

5. The device of claim 4, wherein the first and second insulated-gate field-effect transistors are adjacently disposed along a channel length direction.

6. The device of claim 4, wherein the first element isolation insulation film extends along a channel width direction and is disposed in a manner to sandwich the first insulated-gate field-effect transistor.

7. The device of claim 4, wherein the second element isolation insulation film extends along a channel width direction and is disposed in a manner to sandwich the second insulated-gate field-effect transistor.

8. The device of claim 4, wherein the first and second element isolation insulation films are adjacently disposed along a channel length direction.

9. The device of claim 4, further comprising a contact wiring line provided on the source or the drain, a portion of the contact wiring line being provided on a fringe of each of the first and second element isolation insulation films.

10. The device of claim 4, further comprising a third element isolation insulation film having a negative or positive expansion coefficient, which extends along a gate width direction and is buried in a trench in an element isolation region of the semiconductor substrate in a manner to sandwich each of the first and second insulated-gate field-effect transistors, the third element isolation insulation film, together with the first and second element isolation insulation films, applying a stress by operation heat to each of the first and second insulated-gate field-effect transistors in two axial directions that are a channel length direction and a channel width direction.

11. The device of claim 4, wherein the first element isolation insulation film includes a glass ceramics layer including an amorphous matrix layer and crystal lines dispersed in the amorphous matrix layer, or includes a HfW₂O₈ layer.

12. The device of claim 4, wherein the second element isolation insulation film includes one of a SiO₂ film, an Al₂O₃ film and an AlN film.

13. A method of manufacturing a semiconductor device, comprising:
forming a trench for element isolation in a semiconductor substrate in an element isolation region along two axial directions that are a channel width direction and a channel length direction;
burying a silicon oxide film in the trench;
doping a crystal seed in the silicon oxide film;
performing a first heat treatment process on the silicon oxide film, thereby making the silicon oxide film in a glass state;
performing a second heat treatment process on the silicon oxide film in the glass state, thereby precipitating a crystal nucleus in an amorphous matrix layer in the silicon oxide film;
performing a third heat treatment process on the amorphous matrix layer including the crystal nucleus, thereby growing the crystal nucleus into a crystal line and forming an element isolation insulation film including a glass ceramics layer;
forming a gate insulation film on the semiconductor substrate in an element region;
forming a gate electrode on the gate insulation film; and
forming a source and a drain spaced apart in the semiconductor substrate in a manner to sandwich the gate electrode.

14. The method of claim 13, wherein the first heat treatment process is performed at a higher temperature than the second heat treatment process.

15. The method of claim 14, wherein the second heat treatment process is performed at a lower temperature than the third heat treatment process.

16. The method of claim 15, wherein the third heat treatment process is performed at a lower temperature than the first heat treatment process.

17. The method of claim 14, wherein the second heat treatment process is performed at a temperature at which a rate of formation of the crystal nucleus is highest.

18. The method of claim 14, wherein the third heat treatment process is performed at a temperature at which a rate of growth of the crystal nucleus is highest.
